(19) United States
(12) Patent Application Publication
(10) Pub. No.: US 2011/0177460 A1
(43) Pub. Date: Jul. 21, 2011

(54) PROCESS FOR PRODUCING AN IMAGE ON A SUBSTRATE

(75) Inventor: Xu Shi, Singapore (SG)

(73) Assignee: NANOFILM TECHNOLOGIES INTERNATIONAL PTE LTD, Singapore (SG)

(21) Appl. No.: 12/993,348

(22) PCT Filed: Jun. 9, 2009
(86) PCT No.: PCT/SG2009/000205

§ 371 Date: Apr. 5, 2011

Related U.S. Application Data
(60) Provisional application No. 61/060,021, filed on Jun. 9, 2008.

(51) Int. Cl. G03F 7/20; B05D 1/32; B32B 37/14; C23C 16/44; C23C 14/04; B32B 38/10; B05D 1/12; C23C 14/34; C23C 14/24

(52) U.S. Cl. 430/324; 427/197; 156/247; 427/526; 427/199; 204/192.1; 204/192.38

(57) ABSTRACT

The present invention is directed to a process for producing an image on a substrate and a substrate having an image deposited thereon using the aforementioned processes.

### TECHNICAL FIELD

The present invention generally relates to a process of providing an image on a substrate.

### BACKGROUND

Vapor deposition technology is typically used to form thin film deposition layers in various types of applications, including microelectronic applications and plastic coating applications. In one application, vapor deposition of metallic compounds on the surfaces of glass, ceramic, metal or plastic substrates is a commonly employed technology in the field of microelectronic systems, for example in Micro-Electro-Mechanical Systems (MEMS). The common forms of metallic compounds deposited include soft metals such as aluminum (Al), zinc (Zn), tin (Sn) and alloys thereof. In another application, vapor deposition is used to form uniform, thin metal coatings on the covers of devices such as mobile phones, PDAs and hand-held gaming consoles.

Such deposition technology can be classified in two main categories. A first category of such deposition technology is known as Chemical Vapor Deposition (CVD). CVD generally refers to deposition processes occurring due to a chemical reaction. Common examples of CVD processes include electro-deposition, epitaxy and thermal oxidation. The underlying concept behind CVD lies in the creation of solid materials as a result of direct chemical reactions occurring in the CVD environment. The reactions are typically between gaseous reactants and the solid products thus formed are slowly deposited and built up on the surface of a substrate for a pre-determined amount of time to control the thickness of said deposition.

A second category of deposition is commonly known as Physical Vapor Deposition (PVD). PVD generally refers to the deposition of solid substances occurring as a result of a physical process. The main concept underlying the PVD processes is that the deposited material is physically transferred onto the substrate surface via direct mass transfer. No chemical reaction takes place during the process, and the thickness of the deposited layer is independent of chemical reaction kinetics as opposed to CVD processes.
(1) Sputtering is a known technique for depositing metallic compounds on a substrate, wherein atoms, ions or molecules are ejected from a target material (also called the sputter target) by particle bombardment so that the ejected atoms or molecules accumulate on a substrate surface as a thin film. Sputtering has become one of the most widely used techniques for depositing various metallic films on wafers. Sputtering, however, is a relatively low energy deposition process and results in non-uniform deposition of the ejected particles, thereby causing void formation within the deposited layers. Consequently, the deposited material suffers from inferior adhesion to substrate surfaces, low density and reduced strength. While this problem can be slightly ameliorated by operating the sputtering process at an elevated temperature (e.g. operating temperatures of 300° C. to 700° C.), this results in high energy costs and renders the deposition process unsuitable for heat sensitive substrates such as plastic substrates;
(2) Poor adhesion between the deposited layer and the substrate surface, leading to “chipping” problems in the finished product; and
(3) Sputtering has a greater tendency to introduce impurities in the substrate.

A particular problem with sputtering is that, to avoid the formation of voids, relatively high temperatures are employed which precludes, or at least makes undesirable, the use of plastic substrates in sputtering as plastic deformation occurs. Consequently, while PVD by sputtering may be relatively faster as compared to other PVD processes, is not suitable for use in the deposition of metals and metal compounds onto plastic substrates for generating an image, for the reasons disclosed above.

Another problem associated with forming metal layers on plastic substrates is that the metals deposited on the substrate need to be deposited at a relatively low temperature, otherwise the plastic substrate will melt or deform in shape. Accordingly, in PVD methods, most of the metals and alloys employed have relatively low temperatures and are relatively “soft metals”. Examples of relatively soft metals include such metals as aluminum (Al), Zinc(Zn), Tin (Sn) and copper (Cu). A particular problem with soft metals is that they tend to be readily subject to scratching and deformation when impacted with hard surfaces. Such surface scratching and deformation degrades the overall aesthetics of the metal layer deposited on the plastic substrate. This imparts significant limitations on the deposition of harder metals on plastic substrates, which may be less readily subject to scratching.

There is a need to provide a process for providing an image on a substrate that overcomes or at least ameliorates one or more of the disadvantages described above.

There is also a need to provide a process for depositing a coating on a substrate that does not suffer from the disadvantages listed above.

There is a need to provide a method which allows hard material layers, such as hard metals, to be deposited on a plastic substrate without degradation of the plastic.

### SUMMARY

According to one aspect, there is provided a process for producing an image on a substrate, the process comprising the steps of:
(a) providing a removable film on a portion of the substrate that at least partially surrounds another portion of the substrate that is absent of said removable film and which is in the shape of a predefined pattern representing the image thereon;
(b) projecting particles onto the substrate to deposit a material layer thereon, the portion of the material layer deposited on the substrate that is absent of the removable film forming the image on the substrate; and
(c) removing the removable film from the substrate to leave the image thereon.

The substrate used may be a plastic substrate. In one embodiment, the plastic substrate is polycarbonate.

The process may further comprise the step of applying the removable film on the substrate surface and another step of selectively removing a portion of the removable film to yield an area of substrate surface that is absent of the removable film. In one embodiment, the application step may comprise spin coating the removable film over the substrate surface. The step of selectively removing step may comprise the step of applying a mask over the surface of the removable film-coated substrate, the mask having a predefined pattern which corresponds to the image. Thereafter, the portion of removable film not covered by the mask may be removed to form a portion of substrate surface that is absent of the removable film. In one embodiment, the mask may be a plastic film containing predefined transparent portions. The mask may be removed prior to the subsequent projecting step.

The removable film may be a positive or negative photoresist. In one embodiment, the removable film is a positive photoresist. The portion of the photoresist, not shaded by the mask disposed thereon, may be removed through a photolithography step. The photolithography step may comprise exposing the photoresist to an ultra-violet (UV) radiation source, and thereafter removing the UV-exposed photoresist. This results in a portion of substrate surface being absent of the photoresist. The UV-exposed photoresist may be removed by a developer. The developer may be an aqueous alkali. In one embodiment, the developer may be aqueous sodium hydroxide.

The particles projected in the projecting step may be at least one of ions and atoms. The projection step may comprise at least one of a PVD process and a CVD process. The PVD step may be selected from the group comprising of thermal evaporation, sputtering, ion plating, cathodic arc vapor deposition and filtered cathodic vacuum arc (FCVA). In one embodiment, the projecting step may comprise depositing material on the substrate surface by performing a FCVA deposition step and depositing material by performing a sputtering step.

The projecting step may further comprise depositing material through performing FCVA deposition and sputtering in alternation to form subsequent layers. In one embodiment, the projecting step may be undertaken until a nanofilm of said material layer is disposed on the substrate. Furthermore, multiple nanofilm layers may be formed during the projecting step until a microfilm of said material layer is disposed on the substrate.

The projecting step may comprise the step of depositing metal at least one of ions and atoms onto the substrate. The metal ions are preferably ions of a hard metal. The deposited metal ions may be deposited as pure metals. However, the deposited metal ions may also form metal compounds such as metal nitrides. Exemplary hard metals are hard metals selected from the class of metals chosen from the group consisting of: Scandium (Sc), Titanium (Ti), Vanadium (V), Chromium (Cr), Manganese (Mn), Iron (Fe), Cobalt (Co), Nickel (Ni), Copper (Cu), Yttrium (Y), Zirconium (Zr), Niobium (Nb), Molybdenum (Mo), Technetium (Tc), Rubidium (Ru), Rhodium (Rh), Palladium (Pd), Silver (Ag), Cadmium (Cd), Hafnium (Hf), Tantalum (Ta), Tungsten (W), Rhenium (Re), Osmium (Os), Iridium (Ir), Platinum (Pt), Gold (Au), Mercury (Hg), Rutherfordium (Rf), Dubnium (Db), Seaborgium (Sg), Bohrium (Bh), Hassium (Hs) and Meitnerium (Mt). Exemplary metal compounds may include nitrides, borides, carbides, silicides, and sulfides or any combination thereof, derived from the aforesaid hard metals.

The projecting step may also comprise the step of depositing carbon ions onto the substrate. The carbon ions are preferably ions of a hard amorphous carbon such as diamond-like carbon (DLC). In one embodiment, the hard metal is Chromium (Cr) and the carbon ion is an ionized state of tetrahedral carbon (ta-C) or diamond-like carbon (DLC). In one embodiment, the material layer is comprised of chromium nitride (CrN) and Cr.

The projecting step may comprise the step of projecting hard metal ions and/or atoms onto the substrate to form a hard metal layer thereon. Advantageously, the image can be formed by the hard metal without use of high temperatures, thereby preventing thermal degradation of the plastic substrate.

In one embodiment, there is provided a process for producing an image on a substrate, the process comprising the steps of:

coating a removable film onto a substrate surface;

placing a mask on the substrate, the mask having a predefined pattern representing the image thereon;

removing a portion of the removable film that is either not covered by the mask or which is covered by the mask, to thereby leave a portion of substrate absent of the removable film;

projecting particles onto the substrate to deposit a material layer thereon, the portion of the material layer deposited on the portion of substrate absent of the removable film forming the image on the substrate; and

removing the removable film from the substrate to leave the image thereon.

In another embodiment, there is provided a process for producing an image on a plastic substrate, the process comprising the steps of:

coating a photoresist onto the plastic substrate surface;

placing a mask on the photoresist coated plastic substrate, the mask having a predefined pattern representing the image thereon;

removing a portion of the photoresist that is either not covered by the mask or which is covered by the mask, to thereby leave a portion of plastic substrate absent of the photoresist;

projecting particles onto the substrate to deposit a material layer thereon, the portion of the material layer deposited on the portion of substrate absent of the photoresist forming the image on the substrate, wherein optionally the projecting step is undertaken at a temperature of less than 200 degrees centigrade; and

removing the photoresist from the substrate to leave the image thereon.

The projecting step may be undertaken at a temperature between about 20 degrees centigrade to about 200 degrees centigrade or about 50 degrees centigrade to about 150 degrees centigrade.

The substrate may be a lacquer coated substrate. The lacquer coating may be selected from solvent-based or waterborne clear lacquer coatings. Exemplary lacquers may be chosen from solvent-based or waterborne clear lacquers, having at least one of a hydroxyl group containing and/or amino-group containing binders and polyisocyanate crosslinking agents.

The image is visible to the naked eye and may represent any one or more of an image of a logo, trade mark, identifier, two-dimensional pattern, alphabetical text and numerical text.

In one embodiment, there is provided a process for producing an image on a substrate, the process comprising the steps of:

spin coating a layer of photoresist on said substrate;

providing a mask having a predefined pattern representing the image on said plastic substrate;

performing a photolithography step to remove a portion of the photoresist that corresponds to said predefined pattern of the mask; and

projecting at least one of hard metal atoms, hard metal ions, hard metal compounds and carbocations onto the masked substrate to thereby deposit a layer of hard material thereon, the portion of the hard material layer deposited on the plastic substrate in which the removable film has been removed forming the image on the plastic substrate; and

removing any remaining photoresist to leave the deposited hard material layer on said substrate.

The deposited material may have a Vickers hardness of about 500 kg/mm² at 500 g Vickers loading to more than 1000 kg/mm² at 50 mg Vickers loading.

According to another aspect, there is provided a plastic substrate having an image formed of a hard material on its surface, the image formed by the steps of:
(d) providing a removable film on a portion of the substrate that at least partially surrounds another portion of the substrate that is absent of said removable film and which is in the shape of a predefined pattern representing the image thereon;
(e) projecting particles onto the substrate to deposit a material layer thereon, the portion of the material layer deposited on the substrate that is absent of the removable film forming the image on the substrate; and
(f) removing the removable film from the substrate to leave the image thereon.

Another aspect provides a mobile phone or portable music player cover having an image thereon, the image being made by the steps of:
(g) providing a removable film on a portion of the cover that at least partially surrounds another portion of the substrate that is absent of said removable film and which is in the shape of a predefined pattern representing the image thereon;
(h) projecting particles onto the cover to deposit a material layer thereon, the portion of the material layer deposited on the cover that is absent of the removable film forming the image on the cover; and
(i) removing the removable film from the cover to leave the image thereon.

### Definitions

The following words and terms used herein shall have the meaning indicated:

The term “hard material” as used herein refers to a material such as a pure hard metal, hard metal compound or diamond-like carbon, which has as a characteristic of great hardness and a high resistance to wear. The term encompasses materials having a Vickers hardness of more than 500 kg/mm², typically more than 800 kg/mm² or more than 900 kg/mm² or more than 1,000 kg/mm², for a given Vickers load of 50 mg.

The term “hard metal” as used herein refers to a metal, generally a metal such as Cr, Ti or. W, which has a relatively high hardness and resistance to wear compared to a soft metal such as Al or Zn, and characterized in having a Vickers hardness of at least 500 kg/mm² for a given Vickers load of 50 milligrams. It should be realized that the more than one type of metal may be encompassed by the term, that is, the term also encompasses hard metal alloys.

The term “hard metal compound” means oxides, carbides, nitrides, carbonitrides, silicides and borides of a hard metal as defined above, and mixtures thereof which have a Vickers hardness of 1,000 kg/mm², for a given Vickers load of 50 milligrams.

The term “soft material” as used herein refers to a material such as a pure soft metal, metal compound or amorphous carbon such as graphite, which has as a characteristic of low hardness. The term encompasses materials having a Vickers hardness of less than 500 kg/mm² for a given Vickers load of 50 mg.

The term “soft metal” as used herein refers to a metal, generally a metal such as Al or Zn, which has a relatively low hardness and resistance to wear compared to a hard metal such as Cr, Ti or W, and characterized in having a Vickers hardness of less than 500 kg/mm² for a given Vickers load of 50 milligrams. It should be realized that the more than one type of metal may be encompassed by the term, that is, the term also encompasses soft metal alloys.

The term “soft metal compound” means oxides, carbides, nitrides, carbonitrides, silicides and borides of a hard metal as defined above, and mixtures thereof which have a Vickers hardness of less than 500 kg/mm², for a given Vickers load of 50 milligrams.

The term “diamond-like carbon” and abbreviation thereof, “DLC”, as used herein relates to hard carbon that is chemically similar to diamond, but with the absence of a well-defined crystal structure. Diamond-like carbon are mostly metastable amorphous material but can include a microcrystalline phase. Examples of diamond like carbon include amorphous diamond (a-D), amorphous carbon (a-C), tetrahedral amorphous carbon (ta-C) and diamond-like hydrocarbon and the like. Ta-C is the most preferred diamond like carbon.

The term “nanofilm” refers to a film having a thickness dimension in the nano-sized range of about 1 nm to less than about 1 micron.

The term “microfilm” refers to a film having a thickness dimension in the micro-sized range of about 1 micron to about 10 micron. It should be realized that a microfilm may be comprised of multiple nanofilm layers.

The term “Filtered Cathodic Vacuum Arc” and abbreviation thereof “FCVA” are to be used interchangeably. A method for performing FCVA deposition is disclosed in International patent publication number WO 96/26531, which is incorporated herein in its entirety for reference. The plasma generated in a cathodic arc beam are “filtered” in that they are substantially free of macroparticles.

The term “macroparticles” refers to, in the context of this specification, contaminant particles in a cathodic arc beam. The macroparticles typically have a neutral charge and are large relative to the ions and/or atoms of the plasma. More typically, they are particles that are multi-atom clusters and are visible under an optical microscope in a deposited film using cathodic arc methods.

The term “sputtering” or “sputter deposition” describes a mechanism in which atoms are ejected from a surface of a target material upon being hit by sufficiently energetic particles. Exemplary sputtering deposition is taught by, for example, U.S. Pat. No. 4,361,472 (Morrison, Jr.) and U.S. Pat. No. 4,963,524 (Yamazaki).

The term “photoresist” refers to a light sensitive material, which can be employed in a variety of etching and patterning applications.

The term “positive photoresist” refers to a type of photoresist that becomes soluble to a corresponding developer upon exposure to ultra-violet radiation.

The term “negative photoresist” refers to a type of photoresist that becomes insoluble towards a corresponding developer upon exposure to ultra-violet radiation.

The term “developer” refers to an organic or aqueous medium, which is usually a basic medium, that acts as a solvent for various forms of photoresists compounds.

The word “substantially” does not exclude “completely” e.g. a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

### Disclosure of Optional Embodiments

Exemplary, non-limiting embodiments of a process for producing an image on a substrate will now be disclosed.

The substrate may be a plastic substrate, a glass substrate, a ceramic substrate or a metallic substrate.

The mask may be a photomask, which can be a plastic film having predefined transparent portions thereof, the transparent portions defining a pattern for forming an image.

The removable film may be a photoresist which is removable in a photolithography step. The process may comprise the step of applying a film of photoresist on top of said substrate surface prior to providing the photomask. The photoresist may be a positive photoresist or a negative photoresist or a combination of both.

The photoresist may be spin coated over the substrate surface. Alternatively, the photoresist may also be applied through fluid ejection, dipping, spraying, pouring, thermal evaporation and other suitable vapor deposition processes.

The photolithography process may comprise exposing said plastic substrate coated with said photoresist to an ultra-violet radiation source and removing the UV-exposed photoresist to expose a surface of said plastic substrate absent of said photoresist. Alternatively, the unexposed photoresist portion can be preferentially removed with a negative photoresist developer to expose a clean surface of the plastic substrate.

The developer may be any suitable basic solution, chosen from the group consisting of: hydroxides of Group I and Group II metals, carbonates of Group I and Group II metals, ammonia, and aqueous salts of ammonia.

The developer may also be any suitable organic base acting as a proton acceptor, such as hydrocarbonyl amines, imidazoles, pyridines, histidine, and other nitrogen-containing heterocyclic compounds.

The PVD process may comprise of ion plating, thermal evaporation, sputtering, cathodic arc vapor (CAV) deposition and filtered vacuum cathodic arc (FCVA) deposition.

The PVD process may further comprise employing said sputtering and said FCVA deposition processes in alternation, in succession or a combination of both to form a coating comprised of multiple layers formed by sputtering and PVD. The PVD process may also include other suitable forms of chemical or physical vapor deposition methods, to be used in combination with the FCVA and sputtering processes.

The deposited patterned layer may comprise of alternating layers of metal or metal compounds such as metal carbides, metal nitrides, metal silicides, metal borides or combinations thereof, deposited via either sputtering or FCVA respectively.

The deposited patterned layer may be comprised of a repeating layer, wherein the repeating layer may be comprised of a first layer of material deposited via sputtering and a second layer of material deposited via FCVA. The repeating layer may also comprise of more than layers. The repeating layer may be duplicated as desired to achieve a target thickness required, resulting in a multi-layered arrangement.

The ions/atoms may be positively charged ions(cations)/atoms of elements chosen from the group consisting of: Scandium (Sc), Titanium (Ti), Vanadium (V), Chromium (Cr), Manganese (Mn), Iron (Fe), Cobalt (Co), Nickel (Ni), Yttrium (Y), Zirconium (Zr), Niobium (Nb), Molybdenum (Mo), Technetium (Tc), Rubidium (Ru), Rhodium (Rh), Palladium (Pd), Silver (Ag), Cadmium (Cd), Hafnium (Hf), Tantalum (Ta), Tungsten (W), Rhenium (Re), Osmium (Os), Iridium (Ir), Platinum (Pt), Gold (Au), Mercury (Hg), Rutherfordium (Rf), Dubnium (Db), Seaborgium (Sg), Bohrium (Bh), Hassium (Hs) and Meitnerium (Mt). The ions/atoms may also be positively charged ions(cations)/atoms of elements chosen from the group consisting of: Aluminium (Al), Zinc (Al), Copper (Cu), Lead (Pb), Tin (Sb), Gold (Au), Silver (Ag), Magnesium (Mg), Antimony (Sb), Cadmium (Cd), Thallium (Tl), Bismuth (Bi), Indium (In), Gallium (Ga), Mercury (Hg), Manganese (Mn) and alloys thereof.

The deposited material may have a Vickers hardness ranging from about 500 kg/mm² to about 2000 kg/mm², from about 500 to about 1800 kg/mm², from about 500 to about 1,500 kg/mm², from about 500 to about 1300 kg/mm², from about 500 to 1100 kg/mm², from about 500 to about 1000 kg/mm², from about 500 to about 900 kg/mm², from about 500 to about 800 kg/mm², for a Vickers load of 50 milligrams. Advantageously, the disclosed deposited material may have a Vickers hardness of at least about 1000 MPa, conferring the deposited material with wear resistance and durability.

The deposited material may be a hard metal compound. The hard metal compound may be comprised of oxides, carbides, nitrides, carbonitrides, silicides and borides of hard metals, and/or composite mixtures thereof which have a Vickers hardness of between 500 kg/mm² to more than 1,000 kg/mm².

The hard metals used to form the hard metal compounds may be chosen from the group consisting of: Scandium (Sc), Titanium (Ti), Vanadium (V), Chromium (Cr), Manganese (Mn), Iron (Fe), Cobalt (Co), Nickel (Ni), Yttrium (Y), Zirconium (Zr), Niobium (Nb), Molybdenum (Mo), Technetium (Tc), Rubidium (Ru), Rhodium (Rh), Palladium (Pd), Silver (Ag), Cadmium (Cd), Hafnium (Hf), Tantalum (Ta), Tungsten (W), Rhenium (Re), Osmium (Os), Iridium (Ir), Platinum (Pt), Gold (Au), Mercury (Hg), Rutherfordium (Rf), Dubnium (Db), Seaborgium (Sg), Bohrium (Bh), Hassium (Hs) and Meitnerium (Mt).

The deposited material may be also be at least one of a soft metal, soft metal compound and carbon. In one embodiment, the soft metal compound is at least one of a soft metal oxide, a soft metal carbide, a soft metal nitride, a soft metal carbon nitride, a soft metal silicide and a soft metal boride. The soft metal compound may be comprised of oxides, carbides, nitrides, carbonitrides, silicides and borides of metals, and/or composite mixtures thereof which have a Vickers hardness of less than 500 kg/mm², preferably less than 100 kg/mm² for a given Vickers load of 50 mg.

The soft metals may be chosen from the group consisting of: Aluminium (Al), Zinc (Al), Copper (Cu), Lead (Pb), Tin (Sb), Gold (Au), Silver (Ag), Magnesium (Mg), Antimony (Sb), Cadmium (Cd), Thallium (Tl), Bismuth (Bi), Indium (In), Gallium (Ga), Mercury (Hg), Manganese (Mn) and alloys thereof.

The removal of the photoresist may comprise the step of sonication in a cleaning solution such as isopropyl alcohol to obtain a plastic substrate substantially free of said photoresist.

The filtered vacuum cathodic deposition step may be comprised of applying a negative voltage pulse to a substrate that is electrically conductive, such as metal. The negative voltage pulse may be ranging from about −1800V to about −4500V, from about −2500V to about −4500V, from about −3500V to about −4500V.

The negative voltage pulse may have a frequency ranging from about 1 kHz to about 50 kHz, from about 10 kHz to about 50 kHz, from about 20 kHz to about 50 kHz from about 30 kHz to about 50 kHz, from about 40 kHz to about 50 kHz.

The negative voltage pulse has pulse durations of about 1 μs to about 50 μs, from about 5 μs to about 45 μs, from about 10 μs to about 40 μs and from about 15 μs to about 35 μs.

The sputtering step may deposit a thicker layer of material than the FCVA step. The layer of material deposited using the sputtering step may be about 2 to 15 times thicker than the layer of material deposited using the FCVA step.

The material layer deposited by the sputtering step may be ranging from about 0.1 microns to about 0.5 microns, from about 0.1 microns to about 0.2 microns, from about 0.1 micron to about 0.3 microns, from about 0.1 microns to about 0.4 microns, from about 0.2 microns to about 0.3 microns and from about 0.2 microns to about 0.4 microns, in thickness.

The material layer deposited by the FCVA step ranging from about 0.01 microns to about 0.2 microns, from about 0.01 micron to about 0.12 micron, from about 0.02 micron to about 0.12 micron, from about 0.04 micron to about 0.12 micron, in thickness.

In one embodiment, the projecting step as disclosed herein is carried out at less than about 300° C., less than about 200° C., less than about 100° C. or less than about 70° C.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIG. 1 shows a schematic diagram of a method of forming an image on a plastic substrate in accordance with one disclosed embodiment;

FIG. 2 shows a metal coating layer of a multi-layered film formed by both FCVA and sputtering on a plastic substrate; and

FIG. 3 shows a metal coating layer of a multi-layer film formed by both FCVA and sputtering on a metal substrate.

### DETAILED DESCRIPTION OF DRAWINGS

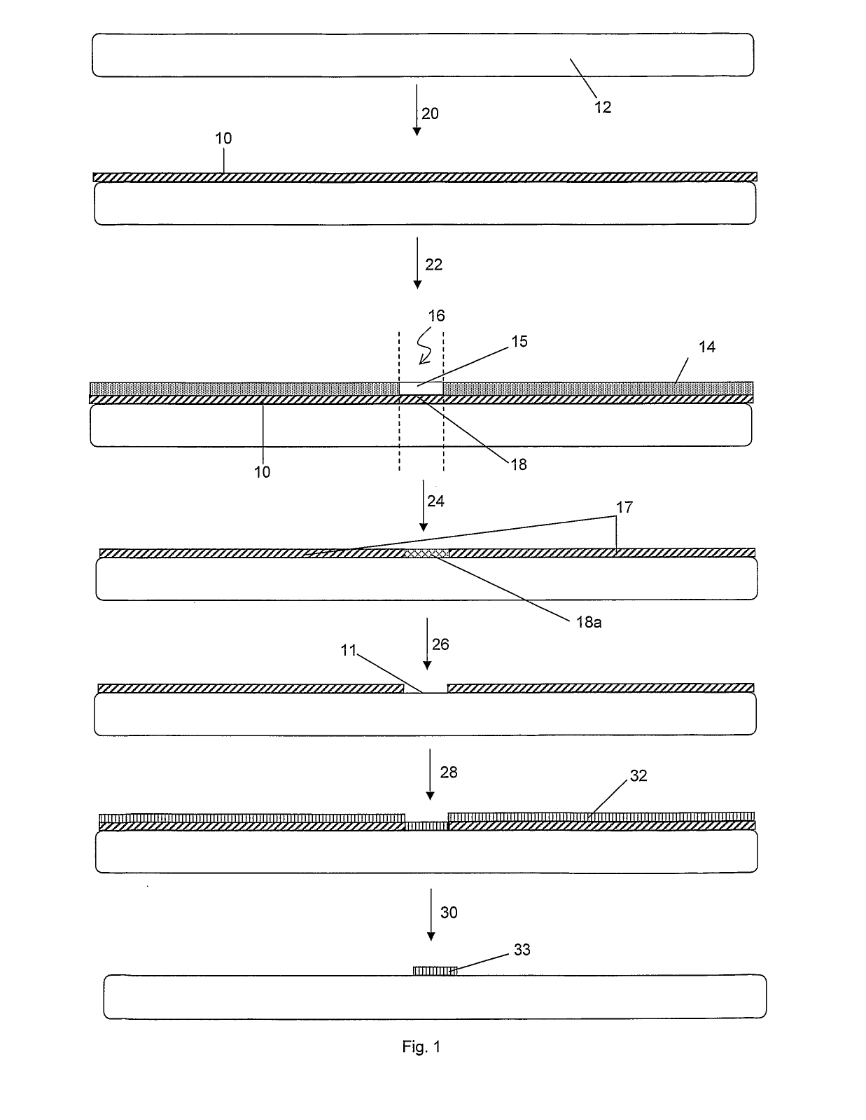

Referring now to FIG. 1, there is shown a process flow chart setting out the steps to a process of providing an image on a plastic substrate.

A plastic substrate 12, coated with a ultra-violet (UV) cured lacquer (not shown), is first provided as the deposition sink. The UV lacquer coating comprises a transparent polymer, cured with UV radiation to form a substantially lustrous finish when viewed with the naked eye. A thin layer of positive photoresist in the form of photoresist layer 10 is applied to the surface of the plastic substrate 12 via a spin-coating process 20. A small volume of the photoresist which forms layer 10 is aspirated using a pipette and applied drop-wise over the surface of the plastic substrate 12, while the plastic substrate 12 is spun at a predetermined speed of revolution for a predetermined amount of time. The plastic substrate 12 is then allowed to dry to enable the photoresist layer 10 to adsorb firmly on the substrate surface. Accordingly, the plastic substrate 12 is integral with the photoresist layer 10.

A mask 14 comprising a patterned design, partially shown in cross-section by the uncovered section 15, is placed on the photoresist layer 10. The uncovered section 15 of the mask defines the desired image that is to be provided on the plastic substrate 10. The uncovered section 15 is permeable to light and exposes an unshaded section 18 of the photoresist. The mask 14 is held in place via the use of mechanical clamps (not shown). After the masking 22 step, the secured mask 14 and photoresist-coated plastic substrate 12 are then simultaneously exposed to ultra-violet (UV) radiation 16 for a pre-determined amount of time. Consequently, the UV-exposed photoresist 18a will be chemically modified by the UV radiation 24 to become soluble in a photoresist solvent (also known as a developer). The developer used here is an aqueous solution of sodium hydroxide (NaOH). However, it should be realized that any suitable solvent for a positive photoresist could be employed here, to attain similar effects and results.

After the predetermined period of UV radiation, the plastic substrate 12 is dipped into a solution containing a photoresist developer 26 to dissolve the exposed photoresist 18. Further washing of the substrate is accomplished by rinsing with deionised water. Accordingly, the UV-exposed photoresist 18a is eroded away by the developer 26 and washed away by the deionised water, exposing a bare region 11 of plastic substrate 12. This exposed region 11 is coincidental with the mask uncovered section 15, and defines the desired region, which is absent of photoresist, to undergo PVD for depositing a resulting image on said plastic substrate.

The next step is the vapor deposition process 28, wherein the plastic substrate undergoes both sputtering deposition and FCVA deposition to form a thin film metal coating layer 32 on both the exposed region 11 and the unexposed photoresist 17. The vapor deposition 28 is carried out until a desired thickness of the metal coating layer 32 is achieved. Once satisfied with the extent of deposition, the final procedure required is the stripping step 30. The unexposed photoresist 17 is removed, together with the metal coating layer 32 coated thereon, via sonication in isopropyl alcohol (IPA). An air gun is subsequently employed to dry the substrate and the patterned layer 33 to remove any remnant solvents.

The finished product is a bare plastic substrate 12 with a patterned layer 33 firmly deposited on its surface.

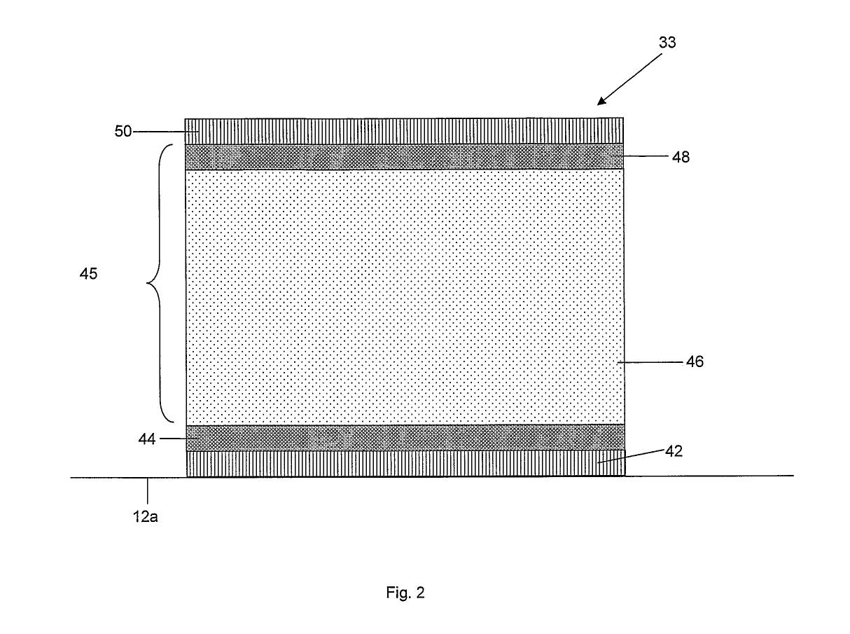

Referring now to FIG. 2, there is shown an enlarged schematic diagram of the deposited patterned layer 33 of FIG. 1. The schematic diagram shows alternating layers of chromium (Cr) and chromium nitride (CrN) deposited in succession of one another. An innermost Cr layer 42 is deposited via FCVA deposition directly onto the surface of the plastic substrate 12. The thickness of the Cr layer 42 is typically about 0.02 microns. Advantageously, in doing so, the heat sensitive plastic substrate will be partially insulated from the high temperatures arising as a result of the subsequent sputtering deposition of succeeding layers. More advantageously, the FCVA layer 42 has strong adhesion to the substrate surface 12a. Even more advantageously, the compact and uniform particle arrangement of the innermost Cr layer 42 provides an ideal seeding layer for subsequent deposition of Cr or CrN. A penultimate CrN layer 44 is then deposited on top of the innermost Cr layer 42, also via FCVA deposition.

Repeating layers 45 are then deposited on top of said CrN layer 44. While only one repeating layer 45 is shown in the Figure, it should be realized that it is merely for the convenience of illustration and in practice, a plurality of “n” repeating layers 45 can be deposited, wherein n range from about 2 to 4.

Each repeating layer 45 is comprised of a sputtered-CrN layer 46 (deposited through a sputtering process) and a FCVA-CrN layer 48 (deposited through a FCVA process). The sputtered-CrN layer 46 is of a much greater thickness relative to the Cr/CrN layers that were deposited using the FCVA process. The thickness of the sputtered-CrN layer 46 is typically from about 0.3 micron while the coupling FCVA-CrN layer is about 0.04 micron. Advantageously, by alternating between layers deposited via sputtering and layers deposited via the FCVA process, the resulting coating 33 enjoys both the benefits of high quality FCVA deposition, the relatively short deposition time as a result of the sputtering of thicker layers, and at the same time minimizing the defects associated with conventional sputtering processes. Also advantageously, the deposited patterned layer 33 is comprised of a hard metal composite CrN which confers a high degree of wear resistance to the resulting image deposited.

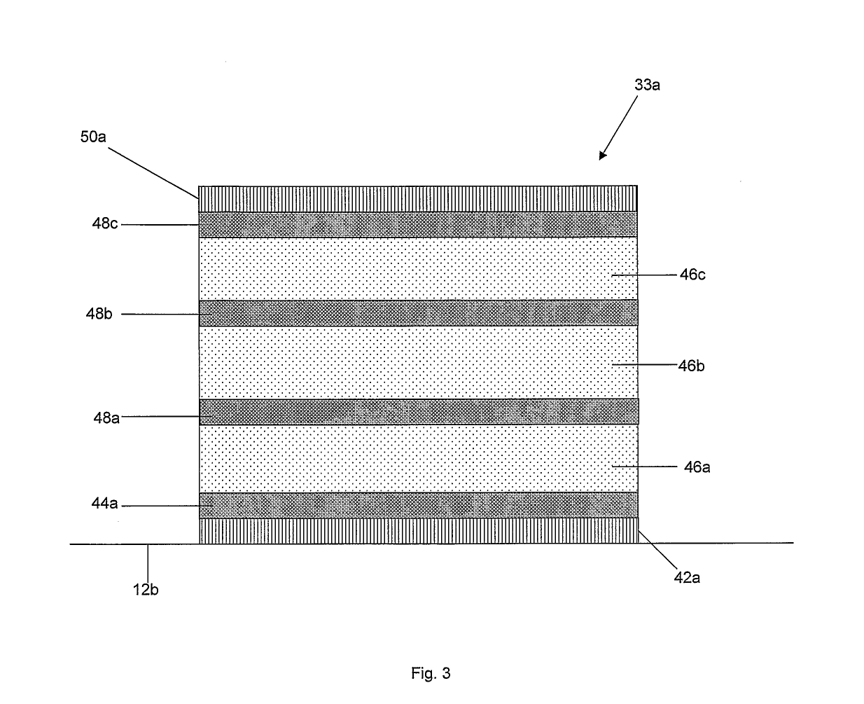

The outermost layer 50 is a shiny, attractive Cr layer deposited using FCVA deposition. Advantageously, this gives the finished coating 33 a polished and shiny appearance and is aesthetically pleasing. This is an exceptionally important aspect for all commercial applications. Now referring to FIG. 3, there is shown another embodiment of the patterned layer 33a deposited on a metallic substrate surface 12b. The patterned layer 33a has a multi-layered arrangement, wherein sputtered-CrN layers (46a, 46b, 46c) are alternated with FCVA-deposited CrN layers (48a, 48b, 48c). The innermost Cr layer 42a is similarly deposited on the metal substrate using the FCVA process. The alternating design advantageously ensures that the resulting patterned layer possesses desirable qualities such as good adhesion, low voidage, high strength, and relatively short deposition time. An optional CrN layer 44a can be deposited adjacent and on top of said innermost layer 42a. The outermost layer 50a is a FCVA-deposited Cr layer to give it a lustrous and aesthetically pleasing finish. Furthermore, as the outermost layer 50a is deposited via the FCVA process, it does not chip readily upon external impact.

Non-limiting examples of the invention, including the best mode, and a comparative example will be further described in greater detail by reference to specific Examples, which should not be construed as in any way limiting the scope of the invention.

### EXAMPLE 1

A plastic substrate, made up of polycarbonate, having an ultra-violet cured lacquer coat of Cashew 4512 was first soaked in aqueous NaOH (concentration of 12.5 grams/litre, Molarity 0.3125M) to increase the surface energy for subsequent photoresist treatment.

The substrate was rinsed with deionised (DI) water and sonicated for 4 minutes. Thereafter, the substrate was blown dry with an air gun and left in an oven to dry at 60° C. for at least 6 hours.

The substrate was then attached to a glass wafer using aluminum (Al) foil tape. The glass wafer was then secured on a spin-coating platform via vacuum suction. The platform was then configured to spin at 1500 rpm for a duration of 20 seconds. A thin layer of positive photoresist of Megaposit™ SPR2FX-1.3, supplied by Rohm and Haas from 100 Philadelphia, United States of America, was then aspirated via a 5 ml pipette and deposited drop-wise onto the surface of the substrate while it underwent spinning. Care was taken to ensure that the glass wafer and substrate are spinning at a constant rate prior to the addition of the photoresist.

The spin-coated substrate is then left to dry in an oven at 60° C. for 30 minutes. Thereafter, a mask, comprising of transparent and opaque sections respectively, is clamped together with the plastic substrate spin-coated with dried photoresist through mechanical clamping. The transparent section in the mask expose certain regions of the dried photoresist and the exposed portion define the desired image to be subsequently formed on the plastic substrate by PVD processes. An exposure to UV radiation for about 30 seconds is applied to the substrate, mask and the exposed regions of the dried photoresist.

After the UV exposure, the mask is removed and the photoresist-coated substrate is dipped into NaOH solution having a concentration of 0.2 M/litre. The exposed photoresist was removed via dissolution into the NaOH solution. Rinsing with DI water further removes any remnants of UV-exposed photoresist still adhering onto the substrate surface. The exposed substrate region was further cleansed via sonication in DI water for 5 minutes in preparation for the vapor deposition process. Finally, the substrate was dried in an oven at 60° C. for 3 hours.

The substrate was then wrapped in Al foil, only exposing the areas which were desired for metallic coating. The coating protocol is shown in Table 1. The innermost Cr layer was deposited via the FCVA process to a thickness of about 0.04 μm. This ensures good adhesion between the substrate surface and the deposited metal film. Optionally, a penultimate CrN layer can be additionally deposited on top of the innermost Cr layer. Next, a repeating layer comprising of at least two alternating CrN layers, deposited via sputtering and FCVA respectively, are evaporated onto the substrate surface. Notably, the sputtered CrN layer was relatively thicker than its corresponding FCVA-deposited layer. This can lead to a considerable reduction in overall deposition time for a desired film thickness, as the sputtering process is generally much faster than FCVA process. In this example, the repeating layer was duplicated once

TABLE 1

| | | Penultimate | Repeating | | |
|---|---|---|---|---|---|
| | Innermost | Layer | layer (s) of n | | Outermost |
| | layer | (Optional) | times | | layer |
| Order | 1 | 2 | 3 | 4 | 5 |
| Method | FCVA | FCVA | Sputtering | FCVA | FCVA |
| Coating | Cr | CrN | CrN | CrN | CrN |
| Thickness | 0.04 | 0.02 | 0.3 | 0.02 | 0.12 |
| (μm) | | | | | |

After the desired film thickness as been reached, the deposition process is stopped and the substrate is subjected to sonication in isopropyl alcohol for 20 minutes to strip the substrate of any remaining photoresist. The removal of the remaining photoresist leaves behind the original plastic substrate, with a patterned metallic film (the image) deposited firmly on its surface.

### Applications

The disclosed process may be used to deposit hard metals and hard metallic compounds onto various substrate surfaces, such as plastic substrates, metal substrates, glass substrates, ceramic substrates and plastic substrates.

Advantageously, multiple nanofilm layer coatings of hard materials can be applied to surfaces. In one aspect, these nanofilm coatings can be applied to plastic substrates to form an image on the plastic substrate without damaging the plastic through heat degradation. Advantageously, multiple nanofilm layers can be applied to a substrate to form a microfilm.

More advantageously, the nanofilm or microfilm layers on the substrate appear, to the naked eye, to be integrally formed with the surface to which they are attached. This provides a good overall aesthetic appeal to the coated article and is particular advantageous when forming images on the article. For example, the disclosed image forming method may be used to make a nanofilm or microfilm coating which represents an image (ie company logo, trade mark, or text) on a plastic device, such as a mobile phone or portable music player. Because the nanofilm and microfilm coatings are made of hard materials, such as chromium or chromium nitride, the images are resistant to scratching and wear, which is particularly advantageous when the mobile phone or portable music player device is being transported by the owner of the device on a day-to-day basis.

Advantageously, in one aspect, the disclosed process allows for the deposition of hard metals, DLC and hard compounds onto plastic substrates, without causing any deformation or damage to the plastic substrates.

The disclosed process employs photolithography to define target regions of the substrate wherein metal deposition is desired. Advantageously, the image as defined by the photolithography method is highly precise. The disclosed photoresist is also easily removed via the application of a developer. Advantageously, the disclosed process does not require complicated multi-step procedures for the precise deposition of a desired image.

In one aspect, the disclosed process employs both sputtering and FCVA processes for the physical vapor deposition step. Advantageously, the disclosed process is able to deposit hard metals onto the plastic substrate without the need for high operating temperatures which would otherwise damage or deform the substrate. The FCVA deposited layer is also substantially free of voids within the metallic layers, thus allowing the formation of a denser and higher quality image. Furthermore, the hard metal coating is also resistant to surface scratching and deformation arising from external impact, which would otherwise compromise the overall aesthetics of the deposited coating.

Also advantageously, in one aspect, the disclosed process enjoys the benefit of a relatively short overall deposition time as a result of employing the sputtering method to deposit some of the layers of the metallic coating in combination with FCVA.

FCVA deposition when used with sputtering boasts of considerable advantages over the use of sputtering alone. Specifically, thin metal films deposited via the FCVA process enjoy better adhesion with the substrate surface. The deposited film is also considerably more closely packed and compact, containing little or no voids therein, as compared to films that were deposited via sputtering processes only.

It should be noted that certain low energy PVD processes, such as sputtering, causes a degree of tensile stress in the coating, while FCVA causes a degree of compressive stress in the coating. Accordingly, when a layer of coating formed by a PVD such as sputtering is alternated with a layer formed by FCVA, the tensile and compressive stresses of the respective layers tends to cancel each other out, or at least reduce the stress effects of the layers in the overall coatings. This results in a reduced stress coating which is not as prone to chipping or flaking of the coating when applied to a substrate.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A process for producing an image on a substrate, the process comprising the steps of:
(a) providing a removable film on a portion of the substrate that at least partially surrounds another portion of the substrate that is absent of said removable film and which is in the shape of a predefined pattern representing the image thereon;
(b) projecting particles onto the substrate to deposit a material layer thereon, the portion of the material layer deposited on the substrate that is absent of the removable film forming the image on the substrate; and
(c) removing the removable film from the substrate to leave the image thereon.

2. The process of claim 1, comprising the step of providing the substrate as a plastic substrate.

3. The process of claim 1, wherein the projecting step (c) comprises projecting at least one of ions and atoms onto the substrate.

4. The process of claim 1, the method further comprising, before step (a), the steps of:
(a1) applying the removable film to the substrate; and
(a2) removing a portion of the removable film from the substrate to form said another portion that is absent of said removable film.

5. The process of claim 4, wherein step (a2) comprises the steps of:
(a2.1) applying a mask on the removable film coated substrate, the mask having a predefined pattern representing the image thereon; and
(a2.2) removing the removable film not covered by said mask to form said another portion that is absent of said removable film.

6. The process of claim 5, further comprising the step of removing said mask before said projecting step (b).

7. The process of claim 2, wherein said plastic substrate further comprises a ultra-violet cured lacquer on the surface of said plastic substrate.

8. The process of any of the preceding claims, wherein said removable film comprises a film of photoresist.

9. The process of claim 8, wherein said photoresist is a positive or negative photoresist.

10. The process of claim 8, further comprising the step of coating the photoresist on the substrate.

11. The process of claim 10, wherein the step of coating comprises at least one of: spin coating the the photoresist on the substrate, pouring the photoresist on the substrate, spraying the photoresist on the substrate or dipping the substrate into the photoresist.

12. The process of claim 5, wherein said removing step (a2.2) comprises a photolithography step.

13. The process of claim 12, wherein said photolithography step comprises:
exposing said plastic substrate coated with said photoresist to an ultra-violet radiation source;
and removing the UV-exposed photoresist to expose a surface of said plastic substrate substantially free of said photoresist.

14. The process of claim 9, wherein said removing step (a2.2) comprises the step of dissolving said UV-exposed photoresist with a developer solution.

15. The process of claim 1, wherein said projecting step comprises at least one of a physical vapor deposition (PVD) step and a chemical vapor deposition (CVD) step.

16. The process of claim 15, wherein said PVD process is selected from the group consisting of thermal evaporation, sputtering, ion plating, cathodic arc vapor deposition and filtered vacuum cathodic arc (FCVA) deposition.

17. The process of claim 1, wherein said projecting step comprises the steps of:
(d) depositing material on a substrate by performing a filtered vacuum cathodic arc deposition step; and
(e) depositing material on a substrate by performing a sputtering step.

18. A process as claimed in claim 17, further comprising the step of repeating alternating steps of at least one of (d) and (e) to form subsequent layers.

19. The process of claim 3, wherein said ions are selected from the group consisting of positively charged ions of hard metals and carbocations, and wherein said atoms are atoms of hard metal elements.

20. The process of claim 1, wherein said deposited material has a Vickers hardness of at least about 500 kg/mm² at a Vickers load of 50 mg or at least about 1000 kg/mm² at a Vickers load of 50 mg.

21. The process of claim 1, wherein said deposited material of step (b) is a hard metal compound.

22. The process of claim 21 wherein said hard metal compound is comprised of a hard metal oxide, a hard metal carbide, a hard metal nitride, a hard metal carbonitride, a hard metal silicide and a hard metal boride.

23. The process of claim 3, wherein said ions are selected from the group consisting of positively charged ions of soft metals and carbocations, and wherein said atoms are atoms of soft metal elements.

24. The process of claim 1, wherein said deposited material has a Vickers hardness of less than 500 kg/mm² at a Vickers load of 50 mg.

25. The process of claim 1, wherein said deposited material of step (b) is a soft metal compound.

26. The process of claim 21 wherein said hard metal compound is comprised of a soft metal oxide, a soft metal carbide, a soft metal nitride, a soft metal carbonitride, a soft metal silicide and a soft metal boride.
